(19) United States
(12) Patent Application Publication
(10) Pub. No.: US 2026/0201608 A1
(43) Pub. Date: Jul. 16, 2026

(54) ALN SINGLE CRYSTAL SUBSTRATE

(71) Applicant: NGK INSULATORS, LTD., Nagoya-shi (JP)

(72) Inventors: Kyohei ATSUJI, Nagoya-shi (JP); Hiroharu KOBAYASHI, Kasugai-shi (JP); Yosuke SATO, Hashima-Gun (JP)

(21) Appl. No.: 19/557,218

(22) Filed: Mar. 5, 2026

Related U.S. Application Data
(63) Continuation of application No. PCT/JP2023/032544, filed on Sep. 6, 2023.

(51) Int. Cl. C30B 29/40; C30B 1/02

(52) U.S. Cl. CPC C30B 29/403; C30B 1/02

(57) ABSTRACT

There is provided an AlN single crystal substrate, which is composed of an AlN single crystal and has a size with a diameter of 100 mm or more.

### CROSS-REFERENCE TO RELATED APPLICATION

This application is a continuation application of PCT/JP2023/032544 filed Sep. 6, 2023, the entire contents of which are incorporated herein by reference.

### BACKGROUND OF THE INVENTION

### 1. Field of the Invention

The present disclosure relates to an AlN single crystal substrate.

### 2. Description of the Related Art

In recent years, AlN single crystal substrates have been developed as base substrates for deep ultraviolet LEDs. A sublimation method has been studied as a method for producing an AlN single crystal. For example, Patent Literature 1 (JP2019-19042A) discloses a method for producing an AlN single crystal, which uses the sublimation method to grow an AlN single crystal on a SiC seed substrate in at least two divided steps.

### CITATION LIST

### Patent Literature

Patent Literature 1: JP2019-19042A

### SUMMARY OF THE INVENTION

When an AlN single crystal is produced by the sublimation method as described above, cracking may occur due to a difference in thermal expansion coefficient between the SiC seed substrate and the AlN single crystal. This problem becomes more pronounced as the substrate size increases. Therefore, it has not heretofore been easy to produce an AlN single crystal substrate having a large size with a diameter of 100 mm or more, without causing cracking.

The present inventors have now found that, by growing an AlN single crystal using an AlN bonded body composed of an AlN seed crystal and an AlN sintered body, it is possible to provide an AlN single crystal substrate that is free from cracking while having a large size with a diameter of 100 mm or more.

Accordingly, it is an object of the present invention to provide an AlN single crystal substrate that is free from cracking while having a large size with a diameter of 100 mm or more.

The present disclosure provides the following aspects.

### [Aspect 1]

An AlN single crystal substrate composed of an AlN single crystal and having a size with a diameter of 100 mm or more.

### [Aspect 2]

The AlN single crystal substrate according to aspect 1, wherein the AlN single crystal substrate has a size with a diameter of 150 mm or more.

### [Aspect 3]

The AlN single crystal substrate according to aspect 1 or 2, wherein an X-ray rocking curve full width at half maximum of a (002) plane of the AlN single crystal on at least one surface of the AlN single crystal substrate is 20 to 350 arcsec.

### [Aspect 4]

The AlN single crystal substrate according to any one of aspects 1 to 3, wherein an X-ray rocking curve full width at half maximum of a (102) plane of the AlN single crystal on at least one surface of the AlN single crystal substrate is 20 to 500 arcsec.

### [Aspect 5]

The AlN single crystal substrate according to any one of aspects 1 to 4, wherein at least one surface of the AlN single crystal substrate has a defect density of 1.0×10³ to 1.0×10⁷ cm⁻².

### [Aspect 6]

A device comprising the AlN single crystal substrate according to any one of aspects 1 to 5.

### BRIEF DESCRIPTION OF DRAWING

FIG. 1 is a process diagram schematically showing the method for producing an AlN single crystal substrate.

### DETAILED DESCRIPTION OF THE INVENTION

### AlN Single Crystal Substrate

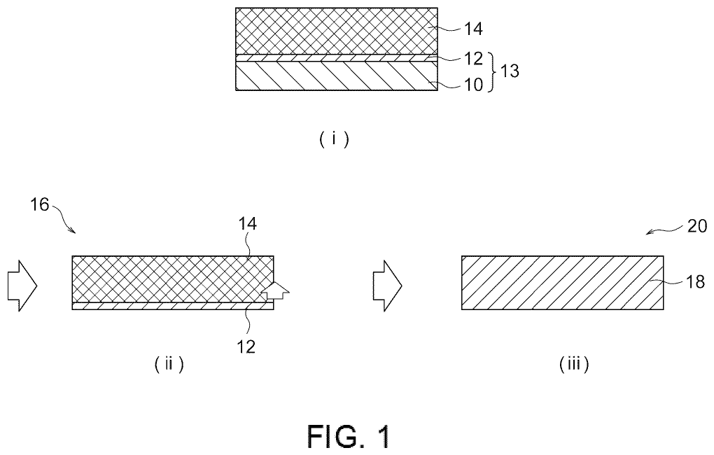

As shown in FIG. 1(iii), an AlN single crystal substrate 20 according to the present invention is composed of an AlN single crystal 18 and has a size with a diameter of 100 mm or more. That is, according to the present invention, it is possible to provide the AlN single crystal substrate 20 that is free from cracking while having a large size with a diameter of 100 mm or more. As described above, when an AlN single crystal is produced by the sublimation method, cracking due to a difference in thermal expansion coefficient between the SiC seed substrate and the AlN single crystal becomes more pronounced as the substrate size increases. Therefore, it has not heretofore been easy to produce an AlN single crystal substrate having a large size with a diameter of 100 mm or more, without causing cracking. In this respect, the AlN single crystal substrate 20 with a large size according to the present invention has been achieved by overcoming this problem in the known art.

The AlN single crystal substrate 20 has a size with a diameter of 100 mm or more, and preferably has a size with a diameter of 150 mm or more or 200 mm or more. While the upper limit of the diameter of the AlN single crystal substrate 20 is not specifically limited, the diameter of the AlN single crystal substrate 20 is typically 300 mm or less, and more typically 250 mm or less. The AlN single crystal substrate 20 typically has a circular shape. As used herein, the “circular shape” need not be a perfect circular shape, but may be a substantially circular shape that can be recognized as a generally circular shape as a whole. For example, the shape may be one in which a portion of the circle is cut out for identification of crystal orientation or other purposes (for example, a circular shape containing an orientation flat or a notch).

While the thickness of the AlN single crystal substrate 20 is not specifically limited, the thickness is preferably 200 to 700 μm, more preferably 250 to 680 μm, and still more preferably 300 to 650 μm.

The AlN single crystal substrate 20 can have good crystallinity. The good crystallinity can be evaluated by measuring a profile of an X-ray rocking curve (hereinafter referred to as “XRC”) of a (002) or (102) plane of the AlN single crystal, and evaluating a full width at half maximum thereof. Specifically, the XRC full width at half maximum of the (002) plane of the AlN single crystal on at least one surface of the AlN single crystal substrate 20 is preferably 20 to 350 arcsec, more preferably 100 to 300 arcsec, and still more preferably 100 to 280 arcsec. When the XRC full width at half maximum of the (002) plane is within these ranges, there is the advantage that, when a device is produced, the formed film has good performance without dislocations. Furthermore, the XRC full width at half maximum of the (102) plane of the AlN single crystal on at least one surface of the AlN single crystal substrate 20 is preferably 20 to 500 arcsec, more preferably 200 to 450 arcsec, and still more preferably 200 to 400 arcsec. When the XRC full width at half maximum of the (102) plane is within these ranges, there is the advantage that, when a device is produced, the formed film has good performance without dislocations. The surface having an XRC full width at half maximum of the (102) plane within the above-mentioned ranges is preferably the same as the surface having an XRC full width at half maximum of the (002) plane within the above-mentioned ranges. Furthermore, preferably, both surfaces of the AlN single crystal substrate 20 have an XRC full width at half maximum of the (102) plane within the above-mentioned ranges and/or an XRC full width at half maximum of the (002) plane within the above-mentioned ranges. Measurement of an XRC profile of the (002) or (102) plane of the AlN single crystal can be performed using a common XRD apparatus (for example, D8 DISCOVER manufactured by Bruker-AXS) and the accompanying XRD analysis software (for example, “LEPTOS” Ver4.03 manufactured by Bruker-AXS), based on the procedure described in the Examples section below.

The AlN single crystal substrate 20 can have a low defect density. Specifically, at least one surface of the AlN single crystal substrate 20 has a defect density of preferably 1.0×10³ to 1.0×10⁷ cm⁻², more preferably 1.0×10⁶ to 8.0×10⁶ cm⁻², and still more preferably 1.0×10⁶ to 6.0×10⁶ cm⁻². When the defect density is within these ranges, there is the advantage that, when a device is produced, the formed film has good performance without dislocations. The surface having a defect density within the above-mentioned ranges is preferably the same surface of the AlN single crystal substrate 20 as the surface having an XRC full width at half maximum of the (102) plane within the above-mentioned numerical ranges and the surface having an XRC full width at half maximum of the (002) plane within the above-mentioned numerical ranges. Furthermore, preferably, both surfaces of the AlN single crystal substrate 20 have a defect density within the above-mentioned numerical ranges. The defect density can be measured based on the procedure described in the Examples section below.

### Device

The AlN single crystal substrate 20 of the present invention has good properties and is also suitable for a large size, thus making it suitable for use as various devices. Therefore, according to a preferred embodiment of the present invention, there is provided a device comprising the AlN single crystal substrate 20. Preferred examples of such devices include deep ultraviolet LEDs, ultraviolet lasers, power devices, MEMS devices, and HMETs (high electron mobility transistors).

### Production Method

A preferred method for producing the AlN single crystal substrate of the present invention will be described below. As shown in FIG. 1, this method comprises the steps of providing an AlN bonded body 16 composed of an AlN seed crystal 12 and an AlN sintered body 14; and subjecting the AlN bonded body 16 to a heat treatment to grow an AlN single crystal 18 from the AlN seed crystal 12. This method can produce an AlN single crystal substrate 20 with high productivity without causing cracking while being a technique suitable for increasing the diameter of the AlN single crystal substrate.

That is, as described above, when an AlN single crystal is produced by the sublimation method, cracking may occur due to a difference in thermal expansion coefficient between the SiC seed substrate and the AlN single crystal. This problem becomes more pronounced as the substrate size increases. One possible solution to this problem may be to perform, for example, the sublimation method only to prepare the AlN seed crystal 12; then, the AlN seed crystal 12 is transferred to the AlN sintered body, and an AlN single crystal is grown from the AlN seed crystal into the region of the AlN sintered body. Thus, it is only required that deposition of the AlN seed crystal 12 by the sublimation method be performed to achieve a thickness that does not cause cracking even in a large size (for example, a diameter of 100 mm or more), and the subsequent growth of the AlN single crystal 18 from the AlN seed crystal 12 is performed by the conversion of the AlN sintered body 14 (AlN polycrystalline body) into the AlN single crystal 18, instead of the sublimation method. In this case, the thermal expansion coefficients of the AlN seed crystal 12 and the AlN single crystal 18 are very similar to each other, so that the possibility that cracking may occur due to the difference in thermal expansion coefficient as in the case of using a SiC seed substrate is extremely low. Therefore, according to the present invention, the AlN single crystal substrate 20 with a large size (for example, a diameter of 100 mm or more) with good quality can be obtained without undergoing a step that is likely to cause cracking.

Each of the steps of the method for producing an AlN single crystal substrate will be described below.

### (1) Providing an AlN Bonded Body

As shown in FIG. 1(ii), the AlN bonded body 16 composed of the AlN seed crystal 12 and the AlN sintered body 14 is provided. The AlN sintered body 14 is an AlN polycrystalline body and is thus a ceramic material composed of a plurality of AlN crystal grains that are bonded together. The AlN bonded body 16 has a diameter of preferably 100 mm or more, and more preferably 150 mm or more or 200 mm or more. The diameter of the AlN bonded body 16 is typically 300 mm or less, and more typically 250 mm or less. While the thickness of the AlN seed crystal 12 is not specifically limited, the thickness is preferably 0.1 to 700 μm, more preferably 0.5 to 450 μm, and still more preferably 1 to 5 μm. While the thickness of the AlN sintered body 14 is not specifically limited, the thickness is preferably 200 to 700 μm, more preferably 250 to 650 μm, and still more preferably 350 to 550 μm.

The AlN bonded body 16 may be provided by any technique as long as it is composed of the AlN seed crystal 12 and the AlN sintered body 14. Preferably, the AlN bonded body 16 is preferably provided by a method shown in the following steps (a) to (c) and FIG. 1(i) and (ii). The order of the steps (a) and (b) may be reversed.

### (a) Providing an AlN Sintered Body

The AlN sintered body 14 is provided. For example, the AlN sintered body 14 can be prepared by mixing an AlN powder and a sintering aid, shaping the resulting mixed powder, and firing the resulting green body. Specifically, the step of providing the AlN sintered body 14 (step (a)) is preferably performed through (a1) preparing a mixed powder; (a2) preparing a green body; and (a3) sintering the green body, as described below. It should be noted that the AlN sintered body 14 may be provided by various known techniques, not limited to the method including the following steps (a1) to (a3).

### (a1) Preparing a Mixed Powder

First, an AlN powder and a powder containing at least one rare earth element is mixed to prepare a mixed powder having an AlN content of 95% by weight or more. The AlN powder is a main component of the mixed powder, while the powder containing the rare earth element is used as a sintering aid. Preferred examples of the rare earth element include Y, La, Ce, Sm, Eu, Gd, Dy, and Yb. These rare earth elements are preferably contained in the powder in the form of oxides, carbonates, hydroxides, or composite oxides. The sintering aid is not limited to the powder containing the rare earth element, and may also be a powder containing an alkaline earth element such as Mg or Ca. The AlN content in the mixed powder is 95% by weight or more, typically 96% by weight or more, more typically 97% by weight or more, and still more typically 98% by weight or more. The content of the sintering aid in the mixed powder is not specifically limited, but is preferably 0.1 to 5.0% by weight, more preferably 0.2 to 4.0% by weight, still more preferably 0.4 to 3.0% by weight, and particularly preferably 0.5 to 2.0% by weight.

### (a2) Preparing a Green Body

The resulting mixed powder is shaped into a predetermined shape to prepare a green body. The shaping method is not specifically limited, and the shaping may be performed by pressing (for example, uniaxial pressing) or sheet forming (for example, a doctor blade method).

### (a3) Sintering the Green Body

The resulting green body is fired to prepare the AlN sintered body 14 with an average crystal grain size of 1 to 40 μm. The firing is preferably performed by hot press firing, which includes holding the green body at a predetermined firing temperature and a predetermined pressure for a predetermined time. The firing temperature during hot press firing is preferably 1500 to 2000° C., more preferably 1600 to 1900° C., and still more preferably 1650 to 1800° C. The holding time at the firing temperature (i.e., firing time) is preferably 1 to 10 hours, more preferably 2 to 8 hours, and still more preferably 4 to 6 hours. The press load during hot press firing is preferably 0 to 30 MPa, more preferably 0 to 20 MPa, and still more preferably 0 to 10 MPa. The average crystal grain size of the AlN sintered body 14 (the average grain size of a plurality of AlN crystal grains constituting the AlN sintered body 14) is 1 to 40 μm, preferably 2 to 25 μm, and more preferably 3 to 10 μm. The average crystal grain size may be measured based on the method described in the Examples section below.

### (b) Providing an AlN Template

As shown in FIG. 1(i), an AlN template 13 is provided. The AlN template 13 is a composite material including the AlN seed crystal 12 and a base substrate 10 supporting the AlN seed crystal 12. The base substrate 10 is preferably a substrate on which the AlN seed crystal 12 can be formed. Preferred examples of the base substrate 10 include a SiC substrate, a sapphire substrate, and a Si substrate. The AlN seed crystal 12 is preferably formed on the base substrate 10 by a vapor phase method. Examples of the vapor phase method include the sublimation method, a chemical vapor deposition (CVD) method, a sputtering method, and a hydride vapor phase epitaxy method (HVPE), with the sublimation method being preferred.

### (c) Bonding the AlN Sintered Body to the AlN Seed Crystal and Removing the Base Substrate

As shown in FIG. 1(i) and (ii), the AlN sintered body 14 is bonded to the AlN seed crystal 12 of the resulting AlN template 13, and the base substrate 10 is removed to obtain the AlN bonded body 16. This bonding may be performed by a surface activation method or plasma bonding. In the case of the surface activation method, the bonding can be preferably performed by the following procedure. First, surfaces of the AlN sintered body 14 are mirror-polished. Next, a surface of the AlN seed crystal 12 and a surface of the AlN sintered body 14 are activated. The surfaces can be activated by irradiation with a neutralized beam such as an Ar beam. Then, the AlN template 13 and the AlN sintered body 14 are placed on each other so that the activated surfaces of the AlN seed crystal 12 and the AlN sintered body 14 are in contact with each other to form a stacked body. The stacked body is bonded by applying a load of 100 to 20000 N under vacuum. After the bonding, the base substrate 10 that is no longer necessary is removed to expose the AlN seed crystal 12, to obtain the AlN bonded body 16 composed of the AlN seed crystal 12 and the AlN sintered body 14. The base substrate 10 can be removed using a known technique such as grinding or reactive ion etching (RIE).

The surface activation with a neutralized beam described above may be performed by introducing an inert gas into a chamber, and applying a high voltage from a direct current power supply to an electrode placed in the chamber. With this structure, electrons are moved by an electric field generated between the electrode (positive electrode) and the chamber (negative electrode), so that beams of atoms and ions are generated by the inert gas. Of the beams that reach a grid, ion beams are neutralized at the grid, so that the beams of neutral atoms are emitted from a fast atomic beam source. The atomic species constituting the beams is preferably an inert gas element (for example, Ar, Ne, Kr, He, N, or Xe). During the activation by beam irradiation, the voltage is, for example, 0.5 to 2.0 kV, and the current is, for example, 50 to 200 mA.

While the AlN sintered body 14 is bonded to only one side of the AlN seed crystal 12 in the example shown in the FIGURE, the AlN sintered body 14 may be bonded to each of both sides of the AlN seed crystal 12.

### (2) Growing an AlN Single Crystal

As shown in FIG. 1(ii) and (iii), the AlN bonded body 16 is subjected to a heat treatment to grow the AlN single crystal 18 from the AlN seed crystal 12. That is, the AlN bonded body 16 is heat-treated, which causes the AlN sintered body 14 to be gradually converted to the AlN single crystal 18 from the portion in contact with the AlN seed crystal 12, which results in growth of the AlN single crystal 18. Unlike the sublimation method in which cracking is likely to occur because of the use of a SiC seed substrate with a thermal expansion coefficient different from that of the AlN single crystal, when this technique is used to grow the AlN single crystal 18, the thermal expansion coefficients of the AlN seed crystal 12 and the AlN single crystal 18 are very similar to each other, so that the AlN single crystal 18 can be grown to a desired thickness without a concern for cracking, even in a large size (for example, a diameter of 100 mm or more). This heat treatment is preferably performed in an inert gas atmosphere such as nitrogen. The firing temperature in the heat treatment is preferably 2000 to 2300° C., more preferably 2100 to 2250° C., and still more preferably 2150 to 2200° C. The holding time at the firing temperature (i.e., firing time) is preferably 1 to 50 hours, more preferably 3 to 45 hours, and still more preferably 5 to 40 hours. This heat treatment may be performed by atmospheric pressure firing or may be performed by hot press firing. The press load during the heat treatment is preferably 0 to 30 MPa, more preferably 0 to 20 MPa, and still more preferably 0 to 10 MPa. Two sheets of the AlN bonded body 16 may be stacked and then subjected to the heat treatment.

In this case, as shown in FIG. 1(ii) and (iii), it is preferred to grow the AlN single crystal 18 over an entire region of the AlN sintered body 14, because this can prevent cracking more effectively. However, as long as cracking does not occur, the AlN single crystal 18 may be grown midway through the AlN sintered body 14 to leave a portion of the AlN sintered body 14 (in this case, it is desired to remove the remaining portion of the AlN sintered body 14 by grinding, for example). By grinding and polishing the surface of the AlN single crystal 18 thus obtained, the free-standing AlN single crystal substrate 20 can be obtained.

### EXAMPLES

The present invention is described in more detail with the following examples. However, the present invention is not limited to the following examples.

### Examples 1 to 11

### (1) Preparation of an AlN Sintered Body

Aluminum nitride powder (manufactured by Tokuyama Corporation, grade F), yttrium oxide powder (manufactured by Shin-Etsu Chemical Co., Ltd.), dysprosium oxide powder (manufactured by Shin-Etsu Chemical Co., Ltd.), and samarium oxide powder (manufactured by Nippon Yttrium Co., Ltd.) were provided. The aluminum nitride powder was mixed with the yttrium oxide powder (Examples 1 to 6 and 9 to 11), dysprosium oxide powder (Example 7) or samarium oxide powder (Example 8) in the weight ratio shown in Table 1 to obtain a blended powder. This blended powder was subjected to uniaxial pressing, and then subjected to hot press firing by heating to the maximum temperature and pressurizing to the maximum pressure shown in Table 1, and holding at the maximum temperature and maximum pressure for the time shown in Table 1. Both surfaces of the resulting hot press fired body were mirror-polished to obtain a platy AlN sintered body (AlN polycrystal).

The average crystal grain size of the resulting AlN sintered body was measured by the following procedure, and the result shown in Table 1 was obtained.

### (Measurement of Average Crystal Grain Size)

The grain size of the sintered body was determined using the intercept method, by mirror-polishing a cross section of the sintered body and examining the microstructure in the range of 64 μm×48 μm with an SEM (JSM-IT500LA manufactured by JEOL Ltd.) at 2000× magnification. Specifically, in the SEM image in which the polished surface of the sintered body was observed, a given number of line segments with a length of 40 μm or more were drawn on the scale of the SEM image, and the number n of crystal grains that those line segments intersected was determined. It should be noted that when an end of a line segment was located in a crystal grain, the crystal grain was counted as ½. A value obtained by dividing the length L of each line segment by n was defined as the average crystal grain size (i.e., average intercept length) I, and a value obtained by multiplying I by a coefficient of 1.5 was defined as the average sintered grain size.

### (2) Preparation of an AlN Template by the Sublimation Method

A SiC substrate as a substrate was placed in a crucible as a crystal growth vessel, and an AlN raw material powder was added while avoiding contact with the SiC substrate. The growth vessel was pressurized at 50 kPa in a N₂ atmosphere, and the portion near the AlN raw material powder in the growth vessel was heated by high-frequency induction heating to 2100° C., while the portion near the SiC substrate in the growth vessel was heated to a temperature lower by 200° C. than that temperature (i.e., 1900° C.). An AlN seed crystal was formed on the SiC substrate by holding at the above-mentioned heating temperature for 30 minutes. The surface of this AlN seed crystal was formed into a mirror surface to obtain a SiC substrate with the AlN seed crystal as an AlN template.

### (3) Bonding of the AlN Sintered Body to the AlN Seed Crystal and Removal of the Base Substrate

The surface of the AlN sintered body and the AlN seed crystal-side surface of the AlN template were irradiated with a fast Ar neutral atom beam (acceleration voltage: 1 kV, Ar flow rate: 60 sccm) for 70 seconds to activate these surfaces. The AlN sintered body and the AlN template were placed on each other so that the AlN sintered body and the AlN seed crystal were in contact with each other, and the AlN sintered body and the AlN template were bonded by applying a load of 1000 N under vacuum. The SiC substrate was removed from the resulting bonded body by grinding with a grinding wheel of the size #2000, and then the surface was further smoothed by lapping with diamond abrasive grains to obtain an AlN bonded body composed of the AlN sintered body and the AlN seed crystal. The AlN bonded body was disk-shaped and had a diameter of 100 mm in Examples 1 to 8 and 150 mm in Examples 9 and 10. The AlN seed crystal had a thickness of 2 μm in Examples 1 to 10 and 4 μm in Example 11. In all of Examples 1 to 11, the AlN sintered body had a thickness of 400 μm.

### (4) Growth of an AlN Single Crystal

The resulting AlN bonded body was subjected to hot press firing for 40 hours under the conditions of 2160° C. and 13 MPa in a N₂ atmosphere, to grow an AlN single crystal from the AlN seed crystal over an entire region of the AlN sintered body.

### (5) Subsequent Step (Grinding and Polishing)

In Examples 1 to 5 and 7 to 10, a predetermined amount of the surface of the resulting AlN single crystal was ground and polished to obtain a free-standing AlN single crystal substrate with a thickness of 0.3 mm. In Example 6 as well, the surface of the AlN single crystal was ground and polished in the same manner as above to obtain a free-standing AlN single crystal substrate with a thickness of 0.3 mm; however, cracking occurred in the AlN single crystal substrate. In Example 11, the AlN single crystal cracked during the growth process, and thus was not subjected to grinding and polishing.

### (6) Evaluation of the AlN Single Crystal

The resulting AlN single crystal was evaluated as follows.

### (6a) Evaluation of the Preparation of the AlN Single Crystal Substrate

The state of AlN single crystal in the step of growth of an AlN single crystal ((4) above) and the subsequent step ((5) above) was observed and evaluated based on the following criteria. The results were as shown in Table 1
Rating A: The AlN single crystal grew without cracking. Also, the AlN single crystal did not crack in the subsequent step (grinding and polishing).
Rating B: The AlN single crystal grew without cracking. Although cracking occurred in the AlN single crystal in the subsequent step (grinding and polishing), it was determined that the cracking could be prevented by changing the conditions in the subsequent step to milder conditions.
Rating C: The AlN single crystal cracked in the growth process, and a free-standing AlN single crystal substrate was not obtained.

### (6b) X-Ray Rocking Curve Full Width at Half Maximum

XRC measurement of the (002) plane of a surface (the surface opposite to the side that was previously the AlN seed crystal) of the AlN single crystal substrate was performed using a multifunctional high-resolution X-ray diffractometer (D8 DISCOVER manufactured by Bruker-AXS). The conditions for the XRC measurement were as follows.

### <XRD Measurement Conditions>

Tube voltage: 40 kV
Tube current: 40 mA
Detector: Tripple Ge (220) Analyzer
CuKα radiation converted to parallel monochromatic light (full width at half maximum: 28 seconds) with a Ge (022) asymmetric reflection monochromator
Step width: 0.001°
Scan speed: 0.5 sec/step

In practice, axial alignment was performed by adjusting 2θ, ω, χ, and φ so that a peak of the (002) plane of the AlN single crystal appeared, and then the range of ω=14.5 to 19.5° was measured at an anti-scattering slit of 3 mm. The full width at half maximum of the XRC profile of the (002) plane of the resulting AlN single crystal was determined using XRD analysis software (“LEPTOS” Ver4.03 manufactured by Bruker-AXS), by performing a peak search after smoothing of the profile. As a result, the full width at half maximum of the (002) plane XRC profile of the surface of the AlN single crystal substrate was as shown in Table 1.

Furthermore, XRC measurement of the (102) plane of a surface (the surface opposite to the side that was previously the AlN seed crystal) of the AlN single crystal substrate was also performed. Using D8 DISCOVER manufactured by Bruker-AXS as the XRD apparatus, axial alignment was performed by adjusting 2θ, ω, χ, and φ so that a peak of the (102) plane of the AlN single crystal appeared, and then measurement was performed at ω=24.5 to 29.5°. The other conditions and analysis method were the same as in the XRC measurement of the (002) plane. As a result, the full width at half maximum of the (102) plane XRC profile of the surface of the AlN single crystal substrate was as shown in Table 1.

### (6c) Defect Density

The defect density of the resulting AlN single crystal substrate (on the surface opposite to the side that was previously the AlN seed crystal) was evaluated by measuring the entire region of the surface by X-ray topography (XRTmicron manufactured by Rigaku Corporation). Here, when the defect density is 1.0×10⁵ cm⁻² or more, it is difficult to accurately calculate the number of etch pits by X-ray topography; thus, etch pit evaluation using molten KOH etching was performed to measure the defect density on the surface of the AlN single crystal substrate. Specifically, in the etch pit evaluation, the surface of the AlN single crystal substrate was immersed for 5 minutes in a molten mixture obtained by mixing KOH and NaOH at a weight ratio of KOH:NaOH=1:1 and heating to 450° C. and etched, and then the defect density was measured with an optical microscope.

### Example 12 (Comparative)

An AlN single crystal was prepared by the sublimation method as follows and then evaluated as in Examples 1 to 11. The results were as shown in Table 1.

### (Preparation of an AlN Single Crystal Substrate)

A SiC substrate with a diameter of 100 mm as a substrate was placed in a crucible as a crystal growth vessel, and an AlN raw material powder was added while avoiding contact with the SiC substrate. The growth vessel was pressurized at 50 kPa in a N₂ atmosphere, and the portion near the AlN raw material powder in the growth vessel was heated by high-frequency induction heating to 2100° C., while the portion near the SiC substrate in the growth vessel was heated to a temperature lower by 200° C. than that temperature (i.e., 1900° C.). An AlN single crystal was deposited and grown on the SiC substrate by holding at the above-mentioned heating temperature for 10 hours. A SiC substrate with the AlN single crystal was obtained. After the temperature dropped, examination of the AlN single crystal showed that cracking (cracks) occurred. It is assumed that because there is a significant difference in thermal expansion between the SiC substrate and the AlN single crystal, the cracking was caused by the thermal stress due to the thermal expansion difference produced during the temperature drop.

TABLE 1

| | | AIN | Conditions and evaluation of preparation of AIN sintered body | | | | | | | Evaluation of AIN single crystal | | | |
|---|---|---|---|---|---|---|---|---|---|---|---|---|---|
| | | seed | Raw material powder | | | Hot press conditions | | | Sintered | Evaluation | (002) peak | (102) peak | |
| | | crystal | AIN | Aid component | | Maximum | Max- | | body | of | full width | full width | Defect |
| | Sample | thick- | powder | | Content | temper- | imum | Holding | Crystal | preparation | at half | at half | density |
| Ex- | diameter | ness | (% by | Compo- | (% by | ature | pressure | time | grain size | of single | maximum | maximum | (×10⁶ |
| ample | (mm) | (μm) | weight) | sition | weight) | (° C.) | (MPa) | (h) | (μm) | crystal | (arcsec) | (arcsec) | cm⁻²) |
| 1 | 100 | 2 | 99.5 | Y₂O₃ | 0.5 | 1650 | 10 | 4 | 2.6 | A | 140 | 220 | 4.0 |
| 2 | 100 | 2 | 98.0 | Y₂O₃ | 2.0 | 1650 | 10 | 4 | 2.3 | A | 150 | 230 | 4.2 |
| 3 | 100 | 2 | 98.0 | Y₂O₃ | 2.0 | 1800 | 10 | 4 | 3.0 | A | 180 | 280 | 4.8 |
| 4 | 100 | 2 | 98.0 | Y₂O₃ | 2.0 | 2000 | 10 | 4 | 4.1 | A | 200 | 310 | 5.1 |
| 5 | 100 | 2 | 98.0 | Y₂O₃ | 2.0 | 2000 | 10 | 10 | 9.8 | A | 320 | 490 | 7.0 |
| 6 | 100 | 2 | 98.0 | Y₂O₃ | 2.0 | 2000 | 10 | 15 | 15 | B | — | — | — |
| 7 | 100 | 2 | 99.5 | Dy₂O₃ | 0.5 | 1650 | 10 | 4 | 2.5 | A | 240 | 230 | 6.5 |
| 8 | 100 | 2 | 99.5 | Sm₂O₃ | 0.5 | 1650 | 10 | 4 | 2.7 | A | 260 | 250 | 6.8 |
| 9 | 150 | 2 | 99.5 | Y₂O₃ | 0.5 | 1650 | 10 | 4 | 2.6 | A | 265 | 250 | 6.9 |
| 10 | 150 | 2 | 98.0 | Y₂O₃ | 2.0 | 1650 | 10 | 4 | 2.3 | A | 160 | 240 | 4.4 |
| 11 | 100 | 4 | 98.0 | Y₂O₃ | 2.0 | 1650 | 10 | 4 | 2.3 | A | 30 | 40 | 0.02 |

| | | | | | | |
|---|---|---|---|---|---|---|
| 12 | 100 | An AIN sintered body was neither prepared nor used. | C | — | — | — |

*represents a comparative example.

What is claimed is:

1. An AlN single crystal substrate composed of an AlN single crystal and having a size with a diameter of 100 mm or more,
wherein an X-ray rocking curve full width at half maximum of a (002) plane of the AlN single crystal on at least one surface of the AlN single crystal substrate is 20 to 350 arcsec.

2. An AlN single crystal substrate composed of an AlN single crystal and having a size with a diameter of 100 mm or more,
wherein an X-ray rocking curve full width at half maximum of a (102) plane of the AlN single crystal on at least one surface of the AlN single crystal substrate is 20 to 500 arcsec.

3. An AlN single crystal substrate composed of an AlN single crystal and having a size with a diameter of 100 mm or more,
wherein at least one surface of the AlN single crystal substrate has a defect density of 1.0×10³ to 1.0×10 cm⁻².

4. An AlN single crystal substrate composed of an AlN single crystal and having a size with a diameter of 150 mm or more.

5. A device comprising the AlN single crystal substrate according to claim 1.

6. A device comprising the AlN single crystal substrate according to claim 2.

7. A device comprising the AlN single crystal substrate according to claim 3.

8. A device comprising the AlN single crystal substrate according to claim 4.
